(19) United States
(12) Patent Application Publication
(10) Pub. No.: US 2013/0216744 A1
(43) Pub. Date: Aug. 22, 2013

(54) METHOD FOR MAKING HOUSING AND HOUSING MADE BY SAME

(71) Applicant: KAI-RONG LIAO, Shenzhen City (CN)

(72) Inventor: KAI-RONG LIAO, Shenzhen City (CN)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 13/593,632

(22) Filed: Aug. 24, 2012

(30) Foreign Application Priority Data
Feb. 21, 2012 (CN) 201210039070.9

(51) Int. Cl. H05K 5/02; B32B 38/04; B32B 37/10; B32B 27/04; B32B 37/12

(52) U.S. Cl. 428/34.5; 428/36.1; 156/222

(57) ABSTRACT

A housing includes a fiber layer, an adhesive layer, and a plastic film bonding the fiber layer by the adhesive layer. The fiber layer is made of fiber woven fabric impregnated with resin. A method for making the present resin-and-fiber composite is also provided.

### BACKGROUND

1. Technical Field

The present disclosure relates to a method for making device housings and a housing made by the method.

2. Description of Related Art

Woven fibers are applied on shells of portable electronic devices and household appliances. A method for making housings using woven fiber includes stacking a plurality of fabric sheets impregnated with resin to form a laminate having a desired thickness. The laminate is cut into a desired shape and size. The laminate is then thermoformed into a housing having a desired shape. However, because the fabric sheets usually have apertures and recesses, the resin on the surface of the laminate flow to fill in the apertures and recesses during the thermoforming process, causing a bumpy surface. Thus, the housing needs to be further processed by filling its surface with resin, then grinding and painting the surface.

Therefore, there is room for improvement within the art.

### BRIEF DESCRIPTION OF THE DRAWINGS

Many aspects of the disclosure can be better understood with reference to the drawing. The components in the drawing are not necessarily drawn to scale, the emphasis instead being placed upon clearly illustrating the principles of the disclosure. Moreover, in the drawings like reference numerals designate corresponding parts throughout the views.

FIG. 1 is a block diagram of a process for making the housing according to an exemplary embodiment.

FIG. 2 is schematic views showing different manufacturing processes in the method of manufacturing the housing according to an exemplary embodiment.

FIG. 3 is a schematic cross-sectional view of an exemplary embodiment of a housing.

### DETAILED DESCRIPTION

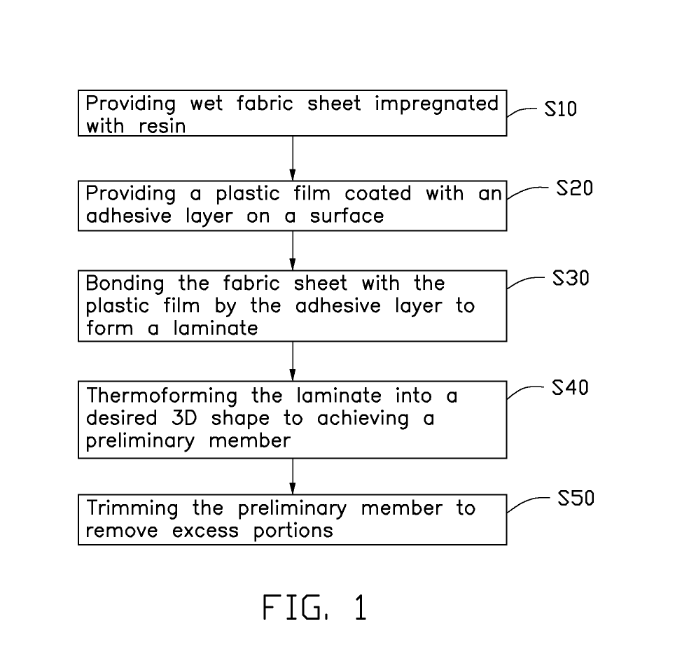

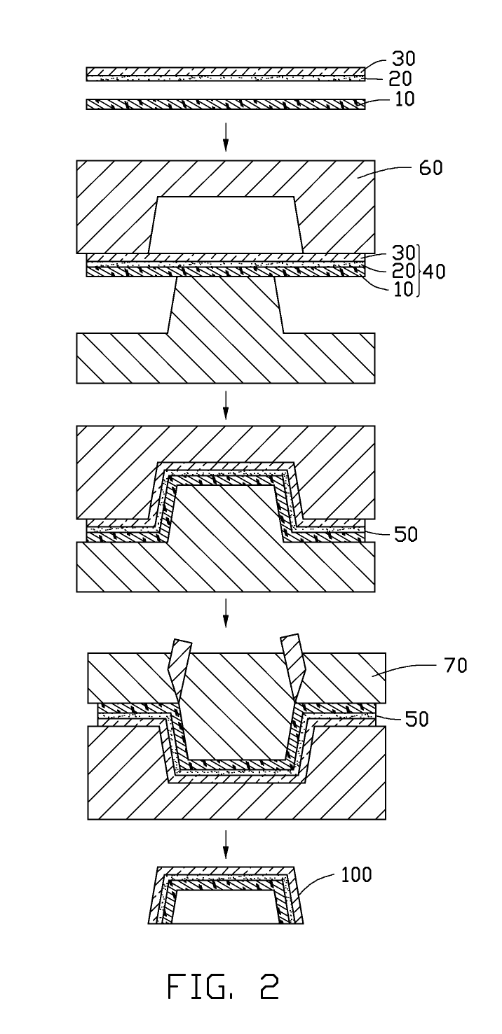

Referring to FIGS. 1 and 2, an exemplary process for making a housing may include the following steps.

In step S10, a fabric sheet 10 impregnated with resin is provided. The fabric sheet 10 may be woven with one fiber material selected from the group consisting of carbon fiber, glass fiber, Para-aramid fiber, and hybrid fiber. In one embodiment, carbon fiber is selected. The fabric sheet 10 may be woven with a desired three-dimensional (3D) texture. The resin may be transparent thermosetting resin, such as epoxy resin.

In step S20, a plastic film 30 coated with an adhesive layer 20 on a surface is provided. The plastic film 30 is transparent and may be made of thermoplastic. The adhesive layer 20 may be a thermosetting adhesive containing epoxy groups. In the exemplary embodiment, the adhesive layer 20 is liquid epoxy resin glue and the plastic film 30 is made of polycarbonate.

In step S30, the fabric sheet 10, still wet with impregnated resin is bonded with the plastic film 30 by the adhesive layer 20 to form a laminate 40. Preferably, the interior of the laminate 40 has no air bubbles, protrusions, or wrinkles.

In step S40, the laminate 40 is thermoformed into a desired 3D shape using a thermoforming die 60, thereby obtaining a preliminary member 50. During the thermoforming process, the thermoforming die 60 may be heated to a temperature of about 100° C. to about 250° C. A pressure of about 10 kg/cm² to about 180 kg/cm² is applied to the laminate 40 through the thermoforming die 60. The thermoforming process takes about 20 minutes to about 60 minutes. After the preliminary member 50 is cooled, the resin in the fabric sheet 10 and the adhesive layer 20 harden, enabling the preliminary member 50 having a rigid 3D shape. When the resin in the fabric sheet 10 is epoxy resin, the temperature of the thermoforming die 60 is set at 170° C. during the thermoforming process.

In step S50, the preliminary member 50 is trimmed to remove excess portions, forming a housing 100 having a desired shape. The plastic film 30 forms a smooth external surface of the housing 100. The fabric sheet 10 is visible through the plastic film 30 and provides the housing 100 with a 3D woven texture.

The order of step S10 and step S20 may be reversed.

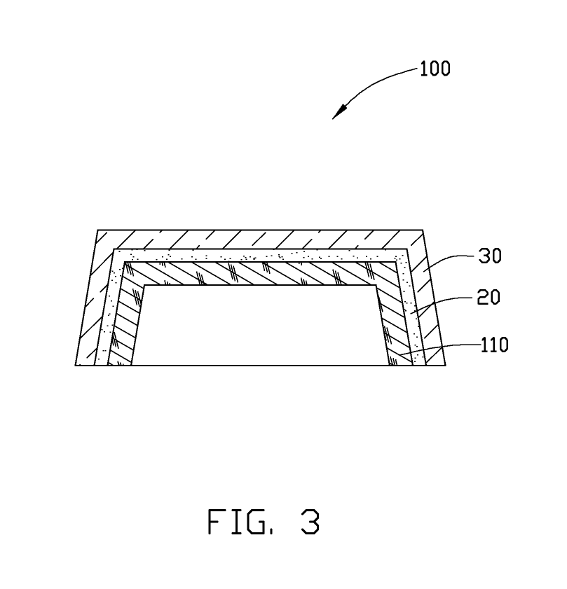

FIG. 3 shows an exemplary housing 100 manufactured by the method described above. In the exemplary embodiment, the housing 100 may be a battery cover of a mobile phone. The housing 100 includes a fiber layer 110, an adhesive layer 20, and a plastic film 30 bonding the fiber layer 110 by the adhesive layer 20.

The fiber layer 110 may be made of fiber woven fabric impregnated with resin. The resin may be transparent thermosetting resin, such as epoxy resin. The fiber woven fabric may be woven with one fiber material selected from the group consisting of carbon fiber, glass fiber, para-aramid fiber, and hybrid fiber. In the exemplary embodiment, carbon fiber is selected. The fiber layer 110 may have a desired woven texture.

The adhesive layer 20 made from a thermosetting adhesive containing epoxy groups. The adhesive layer 20 may have a relative high transparency so the fiber layer 110 is visible through the adhesive layer 20. In the exemplary embodiment, the adhesive layer 20 is made from liquid epoxy resin glue.

The plastic film 30 is transparent and may be made of thermoplastic. In the exemplary embodiment, the plastic film 30 is made of polycarbonate. The thickness of the plastic film 30 may be about 0.2 mm.

The plastic film 30 provides a smooth external surface for the housing 100. Moreover, the woven texture of the fiber layer 110 can be seen by users through the plastic film 30, creating a 3D appearance.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the present disclosure to the full extent indicated by the broad general meaning of the terms in which the appended claims are expressed.

What is claimed is:

1. A method for making a housing, comprising:
providing a fabric sheet wet with impregnated resin, the fabric sheet woven with fiber;
providing a plastic film coated with an adhesive layer on a surface;
bonding the wet fabric sheet with the plastic film by the adhesive layer to form a laminate;
thermoforming the laminate into a desired three-dimensional shape using a thermoforming die, thereby obtaining a preliminary member; and
trimming the preliminary member to remove excess portions.

2. The method as claimed in claim 1, wherein during the thermoforming, the thermoforming die is heated to a temperature of about 100° C. to about 250° C.; a pressure of about 10 kg/cm² to about 180 kg/cm² is applied to the laminate through the thermoforming die.

3. The method as claimed in claim 1, wherein the fiber is selected from the group consisting of carbon fiber, glass fiber, Para-aramid fiber, and hybrid fiber.

4. The method as claimed in claim 1, wherein the resin is transparent thermosetting resin.

5. The method as claimed in claim 1, wherein the plastic film is made of thermoplastic.

6. The method as claimed in claim 5, wherein the plastic film is made of polycarbonate.

7. The method as claimed in claim 1, wherein the adhesive layer is made from a thermosetting adhesive containing epoxy groups.

8. A housing, comprising:
a fiber layer, the fiber layer made of fiber woven fabric impregnated with resin;
an adhesive layer; and
a plastic film bonding the fiber layer by the adhesive layer.

9. The housing as claimed in claim 8, wherein the fiber woven fabric is woven with one fiber material selected from the group consisting of carbon fiber, glass fiber, Para-aramid fiber, and hybrid fiber.

10. The housing as claimed in claim 8, wherein the resin is transparent thermosetting resin.

11. The housing as claimed in claim 8, wherein the plastic film is made of thermoplastic.

12. The housing as claimed in claim 8, wherein the plastic film is transparent.

13. The housing as claimed in claim 8, wherein the plastic film has a thickness of about 0.2 mm.

14. The housing as claimed in claim 8, wherein the adhesive layer is made from a thermosetting adhesive containing epoxy groups.

15. The housing as claimed in claim 14, wherein the adhesive layer is made from liquid epoxy resin glue.
